(19) United States
(12) Patent Application Publication
(10) Pub. No.: US 2026/0344417 A1
(43) Pub. Date: Oct. 29, 2026

(54) OSCILLATING HEAT PIPE INTERPOSER

(71) Applicant: INTERNATIONAL BUSINESS MACHINES CORPORATION, ARMONK, NY (US)

(72) Inventor: Mark D. Schultz, Ossining, NY (US)

(21) Appl. No.: 19/191,352

(22) Filed: Apr. 28, 2025

(51) Int. Cl. H10W 40/22; H10W 40/25; H10W 70/63; H10W 70/66

(52) U.S. Cl. CPC H10W 40/22; H10W 40/258; H10W 70/635; H10W 70/66

(57) ABSTRACT

An oscillating heat pipe (OHP) interposer. The OHP interposer including: a top plate and a bottom plate incorporating through silicon vias (TSVs); and a channel defining structure separate from and coupled to the top plate and the bottom plate. The channel defining structure defines a channel and incorporates the TSVs, and the channel is adapted to be filled with a refrigerant.

### BACKGROUND

The present disclosure relates generally to semiconductor devices, and more specifically to cooling semiconductor devices.

Thermal management is relevant to the operation of semiconductor devices, or integrated circuits. The power density in semiconductor devices continues to increase as circuit density and operating frequency increase. Thermal management includes dissipating heat generated by a semiconductor device away from the device and allowing the generated heat to disperse to its surroundings, while maintaining the semiconductor device at as low a temperature as possible.

High performance semiconductor devices can have one or more “hot spots,” which are regions of the chip having a power density that is substantially greater than an average power density. To insure reliable long-term operation, the thermal management of semiconductor devices can account for these hot spots as well as for the average power density of the semiconductor device.

### SUMMARY

According to some embodiments of the disclosure, there is provided an oscillating heat pipe (OHP) interposer. The OHP interposer includes: a top plate and a bottom plate incorporating through silicon vias (TSVs); and a channel defining structure separate from and coupled to the top plate and the bottom plate. The channel defining structure defines a channel and incorporates the TSVs, and the channel is adapted to be filled with a refrigerant.

According to some embodiments of the disclosure, there is provided a semiconductor module. The semiconductor module includes a processor die, a substrate, and an OHP interposer. The OHP interposer includes: a top plate and a bottom plate incorporating TSVs; and a channel defining structure separate from and coupled to the top plate and the bottom plate. The channel defining structure defines a channel and incorporates the TSVs, and the channel is adapted to be filled with a refrigerant.

According to some embodiments of the disclosure, there is provided a method of fabricating an OHP interposer. The method includes an operation of constructing a channel defining structure, wherein the channel defining structure defines a channel and incorporates TSVs. The method also includes an operation of sandwiching the channel defining structure between a top plate and a bottom plate, wherein the top plate and the bottom plate incorporate the TSVs.

The above summary is not intended to describe each illustrated embodiment or every implementation of the present disclosure.

### BRIEF DESCRIPTION OF THE DRAWINGS

The drawings included in the present application are incorporated into and form part of the specification. They illustrate embodiments of the present disclosure and, along with the description, serve to explain the principles of the disclosure. The drawings are only illustrative of certain embodiments and do not limit the disclosure.

FIG. 1 illustrates a side view of a semiconductor device including an oscillating heat pipe (OHP) enabled module layout, in accordance with some embodiments of the present disclosure.

FIG. 2 illustrates a side view of a semiconductor device including an OHP-enabled module layout, in accordance with some embodiments of the present disclosure.

FIG. 3 illustrates a cross-sectional view of an OHP interposer, in accordance with some embodiments of the present disclosure.

FIG. 4 illustrates a cross-sectional view of an OHP interposer, in accordance with some embodiments of the present disclosure.

FIG. 5 illustrates a cross-sectional view of an OHP interposer, in accordance with some embodiments of the present disclosure.

FIGS. 6, 7, 8, 9, 10 and 11 illustrate steps in a fabrication of an OHP interposer, in accordance with embodiments of the present disclosure.

While the present disclosure is amenable to various modifications and alternative forms, specifics thereof have been shown by way of example in the drawings and will be described in detail. It should be understood, however, that the intention is not to limit the present disclosure to the particular embodiments described. On the contrary, the intention is to cover all modifications, equivalents, and alternatives falling within the spirit and scope of the present disclosure.

### DETAILED DESCRIPTION

Aspects of the present disclosure are directed toward cooling semiconductor devices, and, more specifically, to an oscillating heat pipe (OHP) interposer including a top plate and a bottom plate incorporating through silicon vias (TSVs), a channel defining structure separate from and coupled to the top plate and the bottom plate, wherein the channel defining structure incorporates the TSVs, and the channel is filled with a two-phase coolant such as a refrigerant. While not limited to such applications, embodiments of the present disclosure may be better understood in light of the aforementioned context.

The following example clauses illustrate a non-limiting listing of aspects of the present disclosure. Clause 1 is an OHP interposer that comprises a top plate and a bottom plate incorporating TSVs. The OHP interposer further comprises a channel defining structure separate from and coupled to the top plate and the bottom plate. The channel defining structure defines a channel and incorporates the TSVs, and the channel is filled with a two-phase coolant such as a refrigerant. Advantageously, the aforementioned example can be a component in a semiconductor module and can be located between a processor die and its substrate. The OHP interposer can include power and signal distribution capabilities necessary to support the processor die including any stacked memory located above the die while also providing a cooling solution. The OHP interposer can be built with separate top and bottom plates that can include signal and/or power RDLs and can sandwich the channel defining structure that form channels and interconnects necessary to implement OHPs. The OHPs can move heat from a bottom of the processor die laterally to an area where the heat can be removed from a top of the OHP interposer using a preferred thermal solution (such as a lid, a heat sink, etc.). Heat can simultaneously be removed from the top of the stack of elements that includes the processor die.

Clause 2 includes the features of clause 1. In this example, the OHP interposer further comprises a top power (and/or signal) redistribution layer (RDL) above the top plate and a bottom power (and/or signal) RDL below the bottom plate. Advantageously, in the aforementioned example while the TSVs are constrained in a location to where channel defining structures are located, the interconnect locations to either the substrate on the bottom or the main (processor) die on the top can be required to be in other areas. The RDLs allow for relocation of signal connections to address the requirements of all of the signals.

Clause 3 includes the features of clauses 1 and 2. In this example, the top RDL and the bottom RDL include a plurality of RDL features adapted to allow proper electrical system function and removal of heat utilizing the OHP. These connections and interconnect wiring layers can be similar to those found in the package substrate. Advantageously, in the aforementioned example, the OHP comprising plates, channel defining structures, and the RDL features allow both proper electrical system function and removal of heat utilizing the OHP.

Clause 4 includes the features of clause 1. In this example, the channel has a height of between about 100 micrometers and 200 micrometers. Advantageously, in the aforementioned example, a minimum channel height of somewhere between about 100 and about 200 micrometers can support proper OHP operation.

Clause 5 includes the features of clause 1. In this example, the channel defining structure includes interconnects that include the TSVs. Advantageously, in the aforementioned example, these interconnects provide electrical and power communications between the package substrate and functional dies.

Clause 6 includes the features of clause 1. In this example, the TSVs include a conductive material including copper. Advantageously, in the aforementioned example, copper provides excellent electrical power and signal carrying capability.

Clause 7 includes the features of clause 1. In this example, the channel is continuous and serpentines back and forth between the top plate and the bottom plate. Advantageously, in the aforementioned example, proper coolant distribution in the OHP can be obtained.

Clause 8 is a semiconductor module that comprises a processor die, a substrate and an OHP interposer that comprises a top plate and a bottom plate incorporating TSVs. The OHP interposer further comprises a channel defining structure separate from and coupled to the top plate and the bottom plate. The channel defining structure defines a channel and incorporates the TSVs, and the channel is filled with a two-phase coolant such as a refrigerant. Advantageously, in the aforementioned example, the OHP interposer in the semiconductor module can be located between a processor die and its substrate, The OHP interposer can include power and signal distribution capabilities necessary to support the processor die with its stacked memory while also providing a cooling solution. The OHP interposer can be built with separate top and bottom plates that can include signal and/or power RDLs and can sandwich the channel defining structure that form channels and interconnects necessary to implement OHPs. The OHPs can move heat from a bottom of the processor die laterally to an area where the heat can be removed from a top of the OHP interposer using a preferred thermal solution (such as a lid, a heat sink, etc.). Heat can simultaneously be removed from the top of the stack of elements that includes the processor die.

Clause 9 includes the features of clause 8. In this example, the OHP interposer further comprises a top power (and/or signal) RDL above the top plate and a bottom power (and/or signal) RDL below the bottom plate. Advantageously, the aforementioned example, while the TSVs are constrained in location to where the channel defining structures are, the interconnect locations to either the substrate on the bottom or the main (processor) die on the top may be required to be in other areas. The RDLs allow the relocation of signal connections to address the requirements of all the signals.

Clause 10 includes the features of clauses 8 and 9. Advantageously, in the aforementioned example, the top RDL and the bottom RDL include RDL features that can allow both proper electrical system function and removal of heat utilizing the OHP.

Clause 11 includes the features of clause 8. In this example, the channel has a height of between about 100 micrometers and 200 micrometers. Advantageously, in the aforementioned example, a minimum channel height of somewhere between about 100 and about 200 micrometers can support proper OHP operation.

Clause 12 includes the features of clause 8. In this example, the channel defining structure includes interconnects that include the TSVs. Advantageously, in the aforementioned example, these interconnects provide electrical and power communications between the package substrate and functional dies.

Clause 13 includes the features of claim 8. In this example, the TSVs include a conductive material including copper. Advantageously, in the aforementioned example, copper provides excellent electrical power and signal carrying capability.

Clause 14 includes the features of clause 8. In this example, the channel is continuous and serpentines back and forth between the top plate and the bottom plate. Advantageously, in the aforementioned example, proper coolant distribution in the OHP is obtained.

Clause 15 includes the features of clause 8 and further comprises a lid including at least one heat-reducing component. Advantageously, in the aforementioned example, the lid and the OHP interposer provide double-sided cooling (from a top and a bottom) of the processor die.

Clause 16 includes the features of clause 15. In this example, the at least one heat-reducing component includes a heat sink. Advantageously, in the aforementioned example, the heat sink and the OHP interposer provide double-sided cooling (from a top and a bottom) of the processor die.

Clause 17 includes the features of clause 8. In this example, the OHP interposer is located on the substrate and between the substrate and the processor die. Advantageously, in the aforementioned example, heat generated by lower-level elements can be well extracted using the OHP interposer located between the substrate and the processor die.

Clause 18 includes the features of clause 17. In this example, a lid including at least one heat-reducing component is located above the processor die. Advantageously, in the aforementioned example, the lid and the OHP interposer provide double-sided cooling (from a top and a bottom) of the processor die.

Clause 19 is a method of fabricating an OHP interposer. The method comprises constructing a channel defining structure, wherein the channel defining structure defines a channel and incorporates TSVs and sandwiching the channel defining structure between a top plate and a bottom plate, wherein the top plate and the bottom plate incorporate the TSVs. Advantageously, in the aforementioned example, the OHP interposer can be fabricated with separate top and bottom plates that can sandwich the channel defining structure that form channels and interconnects necessary to implement OHPs. Specific channel features in the top and bottom plates are not required, resulting in stronger top and bottom plates.

Clause 20 includes the features of clause 19 and further comprises attaching a top power redistribution layer (RDL) above the top plate and a bottom power RDL below the bottom plate. Advantageously, in the aforementioned example, the OHP interposer can be fabricated with separate top and bottom plates that can include signal and/or power RDLs and can sandwich the channel defining structure that form channels and interconnects necessary to implement OHPs.

Processor performance, particularly in the field of artificial intelligence (AI), is often limited by bandwidth to memory and/or locally available memory. Three-dimensional (3D) stacking of memory on a processor is one method of improving both. It would be most advantageous for the memory to be stacked on top of the processor to avoid pulling all the processor power and connections through the processor and to avoid system specific memory chip design. Removal of heat from 3D stacks in general and from memory on logic, in particular, can be challenging. Heat generated by lower-level elements cannot be well extracted through the thermal resistance associated with the layers above, particularly with multi-layer memory stacks.

Some version of double-sided cooling (from a top and a bottom of a memory stack) is one potential solution, but none have been implemented in a way that would support the kind of power levels and base logic die size needed for something like an AI chip with high bandwidth memory (HBM) stacks/chiplets on top of it. Embedded two phase cooling can be an approach to solving this problem, but it can require special packaging and a system to deliver and remove refrigerant to and from the die stack. One embedded heat removal technique can involve the use of OHPs.

Embodiments of the present disclosure can include a semiconductor device including an OHP interposer that sits between a processor die and its packaging substrate. The semiconductor device can include power and signal distribution capabilities necessary to support the processor die with its stacked memory. The OHP interposer can be built with separate top and bottom layers that can include signal and/or power redistribution layers (RDL) connected with another set of elements that form channels and interconnects necessary to implement OHPs. Each element of a stack of elements (a top, a bottom, and interconnects) can be thin enough to support reliable TSVs. The OHPs can move heat from a bottom of the processor die laterally to an area where the heat can be removed from a top of the OHP using a preferred thermal solution (such as a lid, a heat sink, etc.). Heat can simultaneously be removed from the top of the stack of elements that includes the processor die.

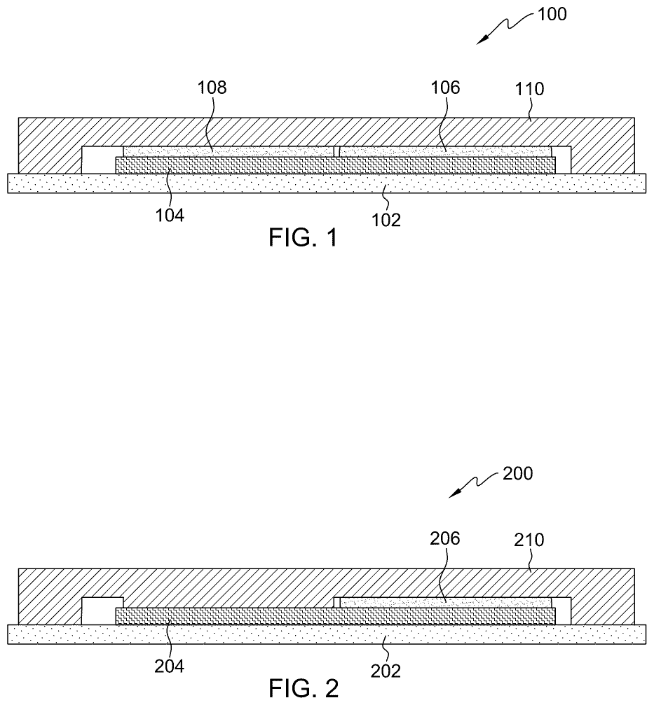

Referring now to the figures, FIG. 1 illustrates a side view of a semiconductor device 100 including an OHP-enabled module layout, in accordance with some embodiments of the present disclosure. The semiconductor device 100 includes a substrate 102. An OHP interposer 104 can be located atop the substate 102. Located on a top surface of the OHP interposer 104, there can be a processor die 106, or active die, or 3D stack or chiplets, on a portion of the OHP interposer 104 and a thermal conductive spacer 108 on some of a remaining portion of the top surface of the OHP interposer 104. A lid 110, or a cooling device or solution (e.g., a heat sink), can be located over the thermal spacer 108 and the processor die 106, and can extend around the thermal spacer 108 and the processor die 106 down to the substrate 102. Coupling between the lid 110 and the processor die 106 and thermal spacer 108 in this figure and others will generally utilize a thermal interface material (TIM).

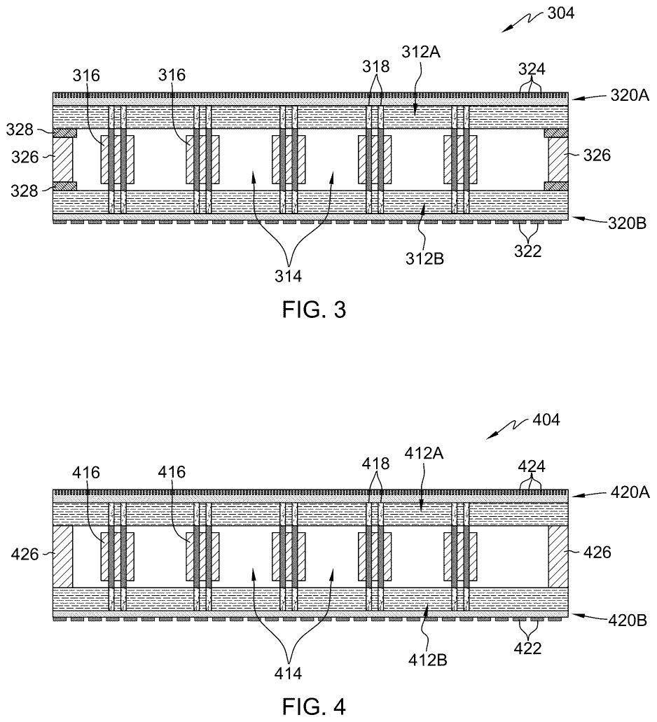

FIG. 2 illustrates a side view of a semiconductor device 200 including an OHP-enabled module layout, in accordance with some embodiments of the present disclosure. The semiconductor device 200 includes a substrate 202. An OHP interposer 204 can be located atop the substate 202. Located on a top surface of the OHP interposer 204, there can be a processor die 206, or active die, or 3D stack or chiplets, on a portion of the OHP interposer 204. A lid 210, or cooling device or solution (e.g., a heat sink), can be located over the processor die 206, and can extend around the processor die 206 down to the substrate 202. A portion of the lid 210 can be located on a portion of the top surface of the OHP interposer 204 where the processor die 206 does not contact the top surface of the OHP interposer 204.

An advantage of the semiconductor devices 100 and 200, shown in FIGS. 1 and 2, can be two-sided heat removal. Heat can be removed from the processor dies 106, 206, respectively, from both top and bottom sides of the processor dies 106, 206. As shown in the figures, the lids 110, 210 (or heat sinks can be used, for example) can remove heat from a top side of the processor dies 106, 206, respectively, and the interposers 104, 204 can remove heat from a bottom side of the processor dies 106, 206, respectively.

Embodiments of the present disclosure can include a OHP interposer with a build structure that allows for TSVs having reliable dimensions. When the TSVs are longer than about 100 micrometers in a passive device and about 50 micrometers in an active device, the TSVs may be unreliable when environmentally stressed.

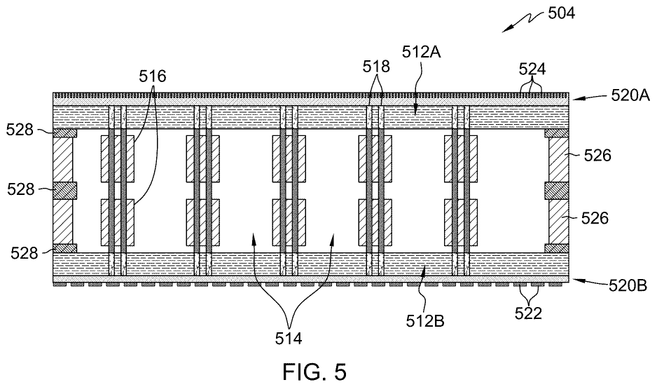

FIG. 3 illustrates a cross-sectional view of an OHP interposer 304, in accordance with some embodiments of the present disclosure. The OHP interposer 304 can include a top plate or die 312A and a bottom plate or die 312B. The top and the bottom dies 312A, B can be made of silicon, for example, although other materials are also contemplated. A plurality of channels 314 (that extend into and out of the page of FIG. 3) can be formed between the top and bottom dies 312A, B that oscillate, or snake, or serpentine back and forth between the top and bottom dies 312A, B and through the OHP interposer 304. A two-phase fluid can run through the plurality of channels 314 and can be used for cooling purposes. Between each of two of the plurality of channels 314, and defining the plurality of channels 314, include a plurality of interconnects 316 (or pads) and two TSVs 318. The TSVs 318 can be made of copper, for example, although other materials are also contemplated by the present disclosure. The TSVs 318 extend into the top die 312A and the bottom die 312B. The interconnects 316 can be made of silicon, for example, although other materials are also contemplated by the present disclosure. The interconnects 316 and TSVs 318 can allow power and/or signals to move through the OHP interposer 304. A top RDL 320A and a bottom RDL 320B can be attached to each of the top die 312A and the bottom die 312B, respectively. The purpose of the RDLs 320A, 320B can be to move electrical and power signals around on a surface of the top and bottom dies 312A, 312B. Required connection locations for both the substrate and the semiconductor dies may differ from the locations provided by the interconnects, requiring redistribution of the connections required by the substrate and dies to those provided by the interconnects. A plurality of connection pads (or bottom RDL features) 322 (typically for solder electrical connections) can be located on an outer surface of the bottom RDL 320B, and a plurality of connection pads (or top RDL features) 324 can be located on the top RDL 320A. The purpose of the bottom RDL features 322 and the top RDL features 324 can be electrically connecting the OHP to the substrate and semiconductor dies respectively. The OHP interposer can also include perimeter walls 326 that can include perimeter bonds/seals 328 between the perimeter walls 326 and the top die 312A and the bottom die 312B. The perimeter walls 326 can be made of, for example, epoxy, or some other similar material.

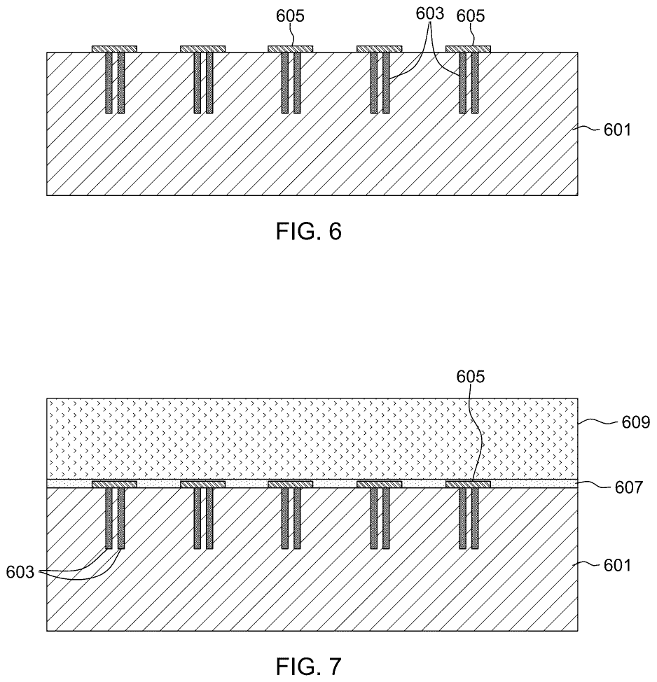

FIG. 4 illustrates a cross-sectional view of an OHP interposer 404, in accordance with some embodiments of the present disclosure. The OHP interposer 404 can include a top plate or die 412A and a bottom plate or die 412B. The top and the bottom dies 412A, B can be made of silicon, for example, although other materials are also contemplated. A plurality of channels 414 (that extend into and out of the page of FIG. 4) can be formed between the top and bottom dies 412A, B that oscillate or snake or serpentine back and forth between the top and bottom dies 412A, B and through the OHP interposer 404. A fluid can run through the plurality of channels 414 and can be used for cooling purposes. Between each of two of the plurality of channels 414, and defining the plurality of channels 414, include a plurality of interconnects 416 (or pads) and two TSVs 418. The TSVs 418 can be made of copper, for example, although other materials are also contemplated by the present disclosure. The TSVs 418 extend into the top die 412A and the bottom die 412B. The interconnects 416 can be made of silicon, for example, although other materials are also contemplated by the present disclosure. The interconnects 416 and TSVs 418 can allow power and/or or signals to move through the OHP interposer 404. A top RDL 420A and a bottom RDL 420B can be attached to each of the top die 412A and the bottom die 412B, respectively. The purpose of the RDLs 420A, 420B can be to move electrical and power signals around on a surface of the top and bottom dies 412A, 412B. Required connection locations for both the substrate and the semiconductor dies may differ from the locations provided by the interconnects, requiring redistribution of the connections required by the substrate and dies to those provided by the interconnects. A plurality of connection pads (or bottom RDL features) 422 can be located on an outer surface of the bottom RDL 420B, and a plurality of connection pads (or top RDL features) 424 can be located on the top RDL 420A. The purpose of the bottom RLD features 422 and the top RDL features 424 can be electrically connecting the OHP to the substrate and semiconductor dies respectively. The OHP interposer can also include perimeter walls 426 that can extend between and connect the top die 412A and the bottom die 412B. The perimeter walls 426 can be made of, for example, epoxy, or some other similar materials.

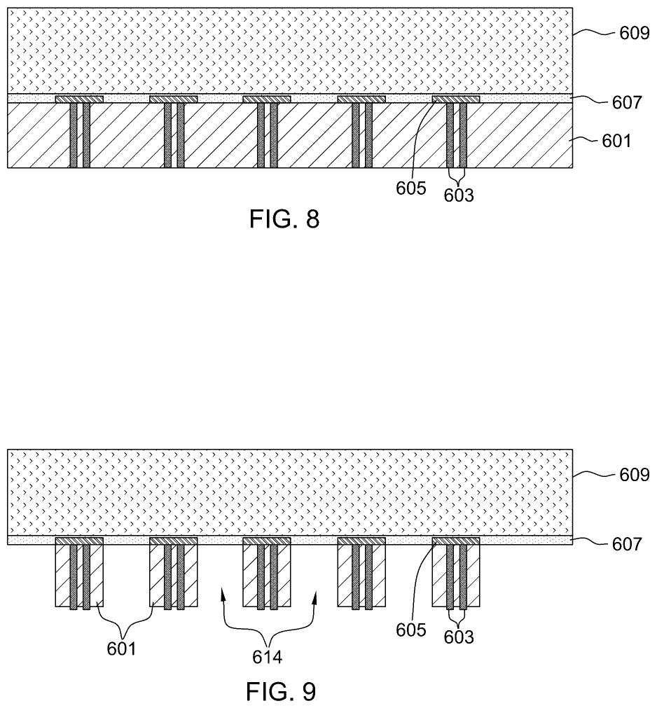

FIG. 5 illustrates a cross-sectional view of an OHP interposer 504, in accordance with some embodiments of the present disclosure. The OHP interposer 504 includes a larger available height if such height might be advantageous for improved OHP heat transfer performance. The OHP interposer 504 can include a top plate or die 512A and a bottom plate or die 512B. The top and the bottom dies 512A, B can be made of can be made of silicon, for example, although other materials are also contemplated. A plurality of channels 514 (that extend into and out of the page of FIG. 5) can be formed between the top and bottom dies 512A, B that oscillate or snake or serpentine back and forth between the top and bottom dies 512A, B and through the OHP interposer 504. The plurality of channels 514 can have a larger height, as shown, than the plurality of channels 314, 414 in FIGS. 3 and 4. A minimum height and a maximum height can be determined by OHP functional behavior. A typical minimum can be about 100 micrometers, but both this and a typical maximum can be dependent on a chosen coolant and a desired performance.

A fluid can run through the plurality of channels 514 and can be used for cooling purposes. Between each of two of the plurality of channels 514, and defining the plurality of channels 514, include a plurality of interconnects 516 (or pads) in sets of two, with one interconnect 516 above another interconnect 516. Two TSVs 518 extend through the interconnects 516 and into the top and the bottom dies 512A, B. The TSVs 518 can be made of copper, for example, although other materials are also contemplated by the present disclosure. The interconnects 516 can be made of silicon, for example, although other materials are by the present disclosure. The interconnects 516 and TSVs 518 can allow power or signals to move through the OHP interposer 504. A top RDL 520A and a bottom RDL 520B can be attached to each of the top die 512A and the bottom die 512B, respectively. The purpose of the RDLs 520A, 520B can be to move electrical and power signals around on a surface of the top and bottom dies 512A, 512B. A plurality of connection pads (or bottom RDL features) 522 can be located on an outer surface of the bottom RDL 520B, and a plurality of connection pads (or top RDL features) 524 can be located on the top RDL 520A. The purpose of the bottom RDL features 522 and the top RDL features 524 can be electrically connecting the OHP to the substrate and semiconductor dies respectively. The OHP interposer 504 can also include perimeter walls 526 that can extend between and connect the top die 512A and the bottom die 512B, and that can include seals 528 to attached portions of the perimeter walls 526. The perimeter walls 526 can be made of, for example, epoxy, or some other similar materials.

The embodiments of the present disclosure relating to the OHP interposer can include a minimum width or height of the plurality of channels of the OHP interposer of between 100 and 200 micrometers. The width or height can be necessary to support operation of the OHP interposer. A configuration of the OHP interposer can include alternating widths of channels, which can imply some channels with sizes larger than 100 to 200 micrometers. With a typical C4 pitch near 150 microns, it can be necessary to redistribute power and signal lines to move them to areas between the plurality of channels where the TSVs can bring the lines vertically through the OHP interposer. If one makes TSVs at a necessary depth, a simple clamshell configuration can be utilized (a top and bottom half, each with a RDL and TSVs) to form the OHP interposer. However, both the limitations on TSV height (100 micrometers or so) and the fragility of silicon with channels can prove to be a challenge.

In some embodiments, a thermal solution can address the top of the die stack to be cooled on one end of the OHP, and the top of the other end of the OHP directly as shown in FIG. 2. In other embodiments, the other end of the OHP might have attached silicon to match the height of the die stack, presenting a uniform height to the thermal solution as shown in FIG. 1.

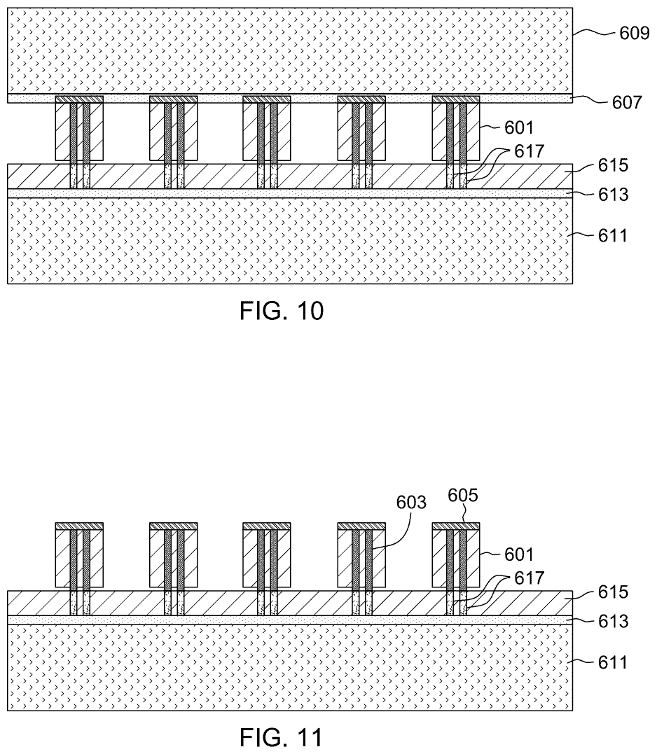

Embodiments of the present disclosure can include a method of making an OHP interposer, such as shown in FIGS. 3-5. An example of fabrication steps is shown in FIGS. 6-11 and described below.

FIG. 6 illustrates a step in a fabrication of an OHP interposer, in accordance with embodiments of the present disclosure. In order to form the structure in FIG. 6, a layer of silicon or other suitable material 601 can be provided. Deep, blind vias can be etched into the silicon layer 601 using a deep reactive ion etch (DRIE) process, and can be filled with a conductive material, such as copper or tungsten, for example, and polished using chemical mechanical polishing (CMP), for example, in order to form TSVs 603. Portions of terminal metal 605, such as copper, aluminum or other typical connection pad metallurgies can be attached to the outer surface of the TSVs 603 using plating, sputtering or other deposition techniques, for example.

FIG. 7 illustrates a step in a fabrication of an OHP interposer, after FIG. 6, in accordance with embodiments of the present disclosure. A top of the silicon layer 601, with the portions of terminal metal 605 can be bonded to a first glass handler 609 using a layer of bonding adhesive 607.

FIG. 8 illustrates a step in a fabrication of an OHP interposer, after FIG. 7, in accordance with embodiments of the present disclosure. A backside grinding process of the silicon layer 601 can be performed. The grinding process can reveal lower ends of the TSVs 603, as shown.

FIG. 9 illustrates a step in a fabrication of an OHP interposer, after FIG. 8, in accordance with embodiments of the present disclosure. A DRIE process can be performed to the backside of the structure in FIG. 8 in order to etch silicon 601 to form interconnects and to form openings between the interconnects that will result in a plurality of channels 614 in a resulting OHP interposer.

FIG. 10 illustrates a step in a fabrication of an OHP interposer, after FIG. 9, in accordance with embodiments of the present disclosure. On the backside of the structure of FIG. 9, a second glass handler 611 with a bond silicon wafer layer 615 including a layer of bond adhesive 613 and. including TSVs 617. The bond silicon wafer 615, with the layer of bond adhesive 613, is shown already thinned and bonded to the glass handler 611.

FIG. 11 illustrates a step in a fabrication of an OHP interposer, after FIG. 10, in accordance with embodiments of the present disclosure. A shown, the first glass handler 609 has been debonded, typically with a laser release process. Stacking of additional components can be performed as needed in order to fabricate an OHP interposer.

The fabrication steps shown in FIGS. 6-11 are shown as a wafer level process. Alternatively, the fabrication steps could be a die-to-wafer process or a die-to-die process.

The embodiments of the present disclosure relating to the method include separately constructing the plurality of channels defining features and sandwiching them between the top and bottom “covers” or plate/die elements of the OHP interposer. These plate/die elements can be constructed by creating TSVs through relatively thin (100 micron) silicon attached to a handler, then etching away the silicon representing the channel areas. These structures can then be attached between the top and bottom plates. Deeper channels can be created by stacking more than one set of channel defining elements. The resulting stack can be perimeter sealed, either with the same basic method that the channels were defined with or by some other means such a sealant or spacer attached to the top and bottom plates. The resulting OHP can be incorporated into a module.

Any of the embodiments can utilize a two-phase refrigerant, such as R-1234ze™, to allow for small channels. Another typical OHP fluid (water) can be used and is contemplated. The RDLs can be added to the individual top and bottom dies or plates prior to OHP interposer construction, but they could be added later, particularly if the OHPs were constructed in an array at wafer level and then diced into individual OHPs. Bonding of the layers in the OHP interposer can be by solder interconnect or thermo-compression bonding or using hybrid oxide-copper bonding. All of this could be die-to-die, die-to wafer, or wafer-to-wafer. Provision can be made for refrigerant fill and sealing as typically required. In a resulting OHP interposer, good thermal conductivity between the bottom of the high-power die and the OHP can be desirable. This can include a high thermal conductivity underfill and/or more interconnect metal and larger final pad vias than may be standard. The OHP interposer can be silicon, including small pad vias for reliable chip to package interconnect performance (chip package interaction or CPI). A large coefficient of thermal expansion (CTE) mismatch interface can be moved to the bottom of the OHP interposer. The resulting OHP interposer can have CPI advantages due to reduced back end-of-line (BEOL) stresses. However, the OHP interposer and its internal connections can be designed and constructed with stress exposures in mind.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments can be practiced. These embodiments were described in sufficient detail to enable those skilled in the art to practice the embodiments, but other embodiments can be used and logical, mechanical, electrical, and other changes can be made without departing from the scope of the various embodiments. In the previous description, numerous specific details were set forth to provide a thorough understanding the various embodiments. But the various embodiments can be practiced without these specific details. In other instances, well-known circuits, structures, and techniques have not been shown in detail in order not to obscure embodiments.

Different instances of the word “embodiment” as used within this specification do not necessarily refer to the same embodiment, but they can. Any data and data structures illustrated or described herein are examples only, and in other embodiments, different amounts of data, types of data, fields, numbers and types of fields, field names, numbers and types of rows, records, entries, or organizations of data can be used. In addition, any data can be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present disclosure has been described in terms of specific embodiments, it is anticipated that alterations and modification thereof will become apparent to the skilled in the art. Therefore, it is intended that the following claims be interpreted as covering all such alterations and modifications as fall within the true spirit and scope of the disclosure.

Any advantages discussed in the present disclosure are example advantages, and embodiments of the present disclosure can exist that realize all, some, or none of any of the discussed advantages while remaining within the spirit and scope of the present disclosure.

What is claimed is:

1. An oscillating heat pipe (OHP) interposer comprising:
a top plate and a bottom plate incorporating through silicon vias (TSVs); and
a channel defining structure separate from and coupled to the top plate and the bottom plate,
wherein the channel defining structure defines a channel and incorporates the TSVs, and the channel is adapted to be filled with a refrigerant.

2. The OHP interposer of claim 1, further comprising:
a top power redistribution layer (RDL) above the top plate and a bottom power RDL below the bottom plate.

3. The OHP interposer of claim 2, wherein the top RDL and the bottom RDL include a plurality of RDL features adapted to allow proper electrical system function and removal of heat utilizing the OHP.

4. The OHP interposer of claim 1, wherein the channel has a height of between about 100 micrometers and 200 micrometers.

5. The OHP interposer of claim 1, wherein the channel defining structure includes interconnects that include the TSVs.

6. The OHP interposer of claim 1, wherein the TSVs include a conductive material including copper.

7. The OHP interposer of claim 1, wherein the channel is continuous and serpentines back and forth between the top plate and the bottom plate.

8. A semiconductor module comprising:
a processor die;
a substrate; and
an oscillating heat pipe (OHP) interposer comprising:
a top plate and a bottom plate incorporating through silicon vias (TSVs); and
a channel defining structure separate from and coupled to the top plate and the bottom plate,
wherein the channel defining structure defines a channel and incorporates the TSVs, and the channel is adapted to be filled with a refrigerant.

9. The semiconductor module of claim 8, wherein the OHP interposer further comprises:
a top power redistribution layer (RDL) above the top plate and a bottom power RDL below the bottom plate.

10. The semiconductor module of claim 9, wherein the top RDL and the bottom RDL include a plurality of RDL features adapted to allow proper electrical system function and removal of heat utilizing the OHP.

11. The semiconductor module of claim 8, wherein the channel has a height of between about 100 micrometers and 200 micrometers.

12. The semiconductor module of claim 8, wherein the channel defining structure includes interconnects that include the TSVs.

13. The semiconductor module of claim 8, wherein the TSVs include a conductive material including copper.

14. The semiconductor module of claim 8, wherein the channel is continuous and serpentines back and forth between the top plate and the bottom plate.

15. The semiconductor module of claim 8, further comprising:
a lid including at least one heat-reducing component.

16. The semiconductor module of claim 15, wherein the at least one heat-reducing component includes a heat sink.

17. The semiconductor module of claim 8, wherein the OHP interposer is located on the substrate and between the substrate and the processor die.

18. The semiconductor module of claim 17, further comprising:
a lid including at least one heat-reducing component, wherein the lid is located above the processor die.

19. A method of fabricating an oscillating heat pipe (OHP) interposer, the method comprising:
constructing a channel defining structure, wherein the channel defining structure defines a channel and incorporates through silicon vias (TSVs); and
sandwiching the channel defining structure between a top plate and a bottom plate,
wherein the top plate and the bottom plate incorporate the TSVs.

20. The method of claim 19, further comprising:
attaching a top power redistribution layer (RDL) above the top plate and a bottom power RDL below the bottom plate.
